(19) United States
(12) Patent Application Publication
(10) Pub. No.: US 2010/0032095 A1
(43) Pub. Date: Feb. 11, 2010

(54) SUBSTRATE PROCESSING APPARATUS

(75) Inventors: Yasuhiro TOBE, Sendai City (JP); Ryou SON, Sendai City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/536,922

(22) Filed: Aug. 6, 2009

(30) Foreign Application Priority Data
Aug. 8, 2008 (JP) 2008-205060

(51) Int. Cl. C23F 1/08; C23C 14/56; C23C 16/54

(52) U.S. Cl. 156/345.51; 204/298.15; 118/719

(57) ABSTRACT

The processing device includes a processing chamber which receives the substrate, a depressurization mechanism which depressurizes the interior of the processing chamber, a stage which holds the substrate and is arranged in the processing chamber, a linear movement mechanism which linearly moves the stage and is arranged in the processing chamber, and a parallel link mechanism which prevents the rotation of the stage and is arranged in the processing chamber. A space portion isolated from the internal atmosphere of the processing chamber is formed in the stage. An air communication path that allows the space portion to communicate with the external atmosphere of the processing chamber is formed in the parallel link mechanism.

### CROSS-REFERENCE TO RELATED PATENT APPLICATIONS

This application claims the benefit of Japanese Patent Application No. 2008-205060, filed on Aug. 8, 2008, in the Japan Patent Office, the disclosure of which is incorporated herein in its entirety by reference.

### BACKGROUND OF THE INVENTION

1. Field of the Invention

The present invention relates to an apparatus for performing a predetermined process with respect to a substrate in the interior of a depressurized processing chamber.

2. Description of the Related Art

Organic electroluminescence (EL) devices utilizing EL have been recently developed. The organic EL devices rarely generate heat, and thus a power consumption thereof is lower than that of cathode ray tubes. In addition, since the organic EL devices are self-emissive devices, they have advantages such as a wider viewing angle, compared to liquid crystal displays (LCDs), and thus, future growth of the organic EL devices is being expected. A conventional organic EL device basically has a sandwich structure in which an anode (positive electrode) layer, a light-emitting layer, and a cathode (negative electrode) layer are stacked on a glass substrate. In order to lead a light emitted from the light-emitting layer to the outside, a transparent electrode formed of indium tin oxide (ITO) is used as the anode layer on the glass substrate. The conventional organic EL device is generally fabricated by sequentially forming the light-emitting layer and the cathode layer on the glass substrate. The ITO layer (the anode layer) is formed in advance on a surface of the glass substrate.

In a process of forming the light-emitting layer of the organic EL device, while a substrate is transferred in a processing chamber that is depressurized to a predetermined pressure level, film forming vapor is supplied at a high temperature of about 200° C.-500° C. from a deposition head (a vaporization head) to deposit the film-forming material on a surface of the substrate. Thus, although a substrate transfer apparatus exists in the processing chamber, when the processing chamber is depressurized, a contaminant is generated from the substrate transfer apparatus, which may exert a bad influence on the film forming process. That is, a typical substrate transfer apparatus includes a linear guide for guiding a stage holding the substrate along a linear path, a driving motor for moving the stage, and a metal roller. Thus, when the interior of the processing chamber is depressurized, grease, which is used as a lubricant for the linear guide, may vaporize. Then, the vaporized grease may be mixed as a contaminant into the light-emitting layer of the organic EL device.

Thus, a magnetic levitation vacuum transfer apparatus that transfers a transfer stage, on which a substrate is placed, in a non-contact state in a vacuum tunnel by using a magnetic force, has been suggested (see Patent Document 1). Also, although not under a depressurization environment, in the field of apparatuses for processing a work by spraying a liquid powder onto the work, a transfer apparatus using a linear movement mechanism, such as a peaucellier linkage, has been widely known (see Patent Document 2).

[Patent Document 1] Japanese Patent Laid-Open Publication No. hei 6-179524

[Patent Document 2] Japanese Patent Laid-Open Publication No. 2000-198070

However, the magnetic levitation vacuum transfer apparatus disclosed in Patent Document 1 has a complicated structure and may generate contamination due to particles generated from the linear motor. Also, the transfer apparatus disclosed in Patent Document 2 is assumed to be installed in the air. Thus, in the processing chamber in a depressurization environment, forming of a link mechanism such as the peaucellier linkage conventionally has not been taken into consideration.

### SUMMARY OF THE INVENTION

To solve the above and/or other problems, according to the present invention, a substrate is transferred in a depressurized process chamber without generating contamination.

According to the processing apparatus of the present invention, a processing device for processing a substrate includes a processing chamber which receives the substrate, a depressurization mechanism which depressurizes the interior of the processing chamber, a stage which holds the substrate and is arranged in the processing chamber, a linear movement mechanism which linearly moves the stage and is arranged in the processing chamber, and a parallel link mechanism which prevents the rotation of the stage and is arranged in the processing chamber, wherein a space portion isolated from the internal atmosphere of the processing chamber is formed in the stage, and an air communication path that allows the space portion to communicate with the external atmosphere of the processing chamber is formed in the parallel link mechanism.

The linear movement mechanism may include a peaucellier linear movement mechanism. The processing device may further include a driving source which drives the linear movement mechanism, wherein the driving source is arranged outside the processing chamber. The parallel link mechanism may include a plurality of arms connected to be capable of being freely rotated with respect to each other. A convex portion having a cylindrical shape and formed at one of the plurality of arms may be inserted in a concave portion having a cylindrical shape and formed at the other arm, at a connection portion between the plurality of arms forming the parallel link mechanism, to connect the plurality of arms to be capable of being freely rotated with respect to each other, and a shaft receiving member and a sealing member may be formed between an outer circumferential surface of the convex portion and an inner circumferential surface of the concave portion. The sealing member may be arranged closer to the internal atmosphere of the processing chamber than the shaft receiving member, and the shaft receiving member may be arranged close to atmosphere in the arm sealed by the sealing member. The sealing member may include a magnetic fluid.

Also, The processing device may further include a bent portion formed on one of the plurality of arms forming the parallel link mechanism to be wide to the outside, to increase a bending angle between the arms at a connection portion between the plurality of arms. An electric wiring or a fluid path may be arranged in the arm. A gas pipe may be arranged in the arm.

Also, the processing device may further include a deposition head which supplies vapor of a film-forming material to the substrate held on the stage, wherein the deposition head is provided in the processing chamber. The film-forming material may include a film-forming material of a light-emitting layer of an organic electroluminescence (EL) device.

### BRIEF DESCRIPTION OF THE DRAWINGS

The above and other features and advantages of the present invention will become more apparent by describing in detail exemplary embodiments thereof with reference to the attached drawings in which:

FIG. 1 is a view illustrating an organic electroluminescent (EL) device;

FIG. 2 is a view illustrating a film forming system;

FIG. 3 is a perspective view of a deposition processing apparatus according to an embodiment of the present invention;

FIG. 4 is a partial cross sectional view illustrating the internal structure of the deposition processing apparatus.

FIG. 5 is a cross-sectional view illustrating a bottom surface of a processing chamber that a shaft of a motor penetrates;

FIG. 6 is a plan view of a transfer apparatus;

FIG. 7 is a schematic diagram illustrating a change in the positional relationship of the respective links, arms, and rotation axes of the linear movement mechanism and the parallel link mechanisms;

FIG. 8 is a cross-sectional view illustrating the internal structure of a stage;

FIG. 9 is a magnified cross-sectional view illustrating the connection structure of the arms; and

FIG. 10 is a view illustrating the state in which the stage moves linearly, not by being rotated.

### DETAILED DESCRIPTION OF THE INVENTION

Hereinafter, the present invention will be described in detail by explaining exemplary embodiments of the invention with reference to the attached drawings. In the embodiments of the present invention, as an example of substrate processing in a depressurization environment, a processing system for fabricating an organic electroluminescence (EL) device by forming an anode (positive electrode), a light-emitting layer, and a cathode (negative electrode) on a glass substrate will be described in detail. In the present specification and drawings, like reference numerals in the drawings denote like elements, and thus their descriptions will be omitted herein.

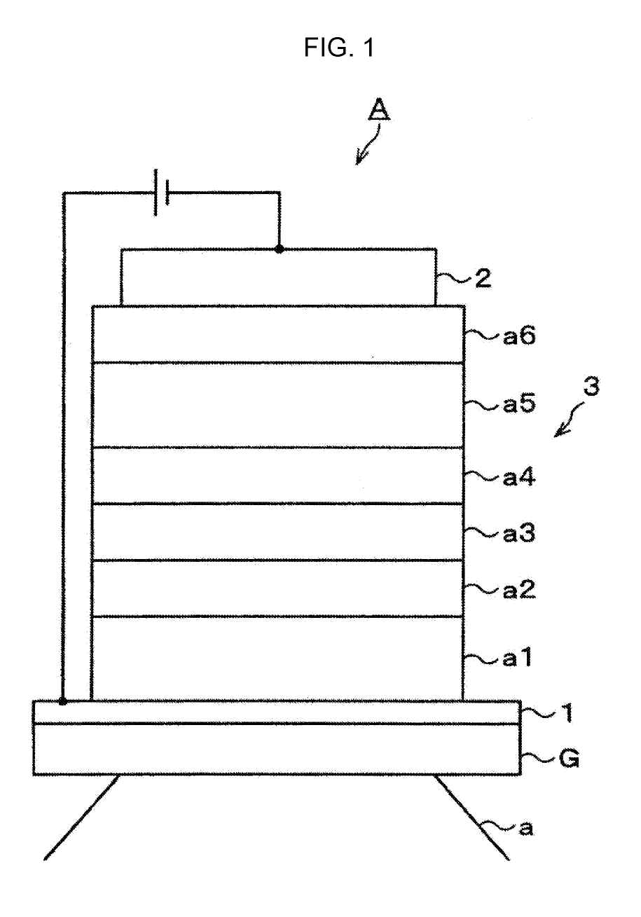

FIG. 1 is a view illustrating an organic EL device A according to an embodiment of the present invention. The organic EL device A basically has a sandwich structure in which a light-emitting layer 3 is interposed between an anode 1 and a cathode 2. The anode 1 is formed on a glass substrate G. The anode 1 may be a transparent electrode formed of, for example, indium tin oxide (ITO), through which light ‘a’ emitted from the light-emitting layer 3 is transmitted.

The light-emitting layer 3, that is, an organic layer, may have a single-layered structure or a multi-layered structure. The light-emitting layer 3 illustrated in FIG. 1 has a six-layered structure including a first layer a1 to a sixth layer a6. The first layer al is a hole transport layer, the second layer a2 is a non-emissive layer (an electron blocking layer), the third layer a3 is a blue light emission layer, the fourth layer a4 is a red light emission layer, the fifth layer a5 is a green light emission layer, and the sixth layer a6 is an electron transport layer. As described later, The organic EL device A is fabricated by sequentially forming the light-emitting layer 3 (the first layer al to the sixth layer a6) on and above the anode 1 formed on a surface of the glass substrate G, for example, providing a work function adjusting layer (not shown), forming the cathode 2 using Ag or a Mg/Ag alloy, and finally sealing the entire structure with a nitride layer (not shown).

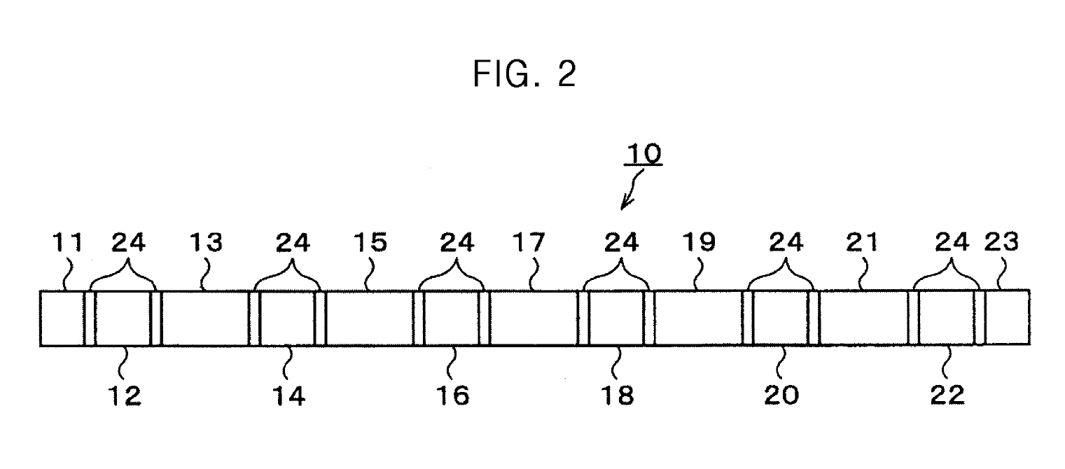

FIG. 2 is a view illustrating a film forming system 10 for fabricating the organic EL device A of FIG. 1, according to an embodiment of the present invention. Referring to FIG. 2, the film forming system 10 includes a loader 11, a transfer chamber 12, a deposition processing device 13 for forming the light-emitting layer 3, a transfer chamber 14, a work function adjusting film forming device 15, a transfer chamber 16, an etching device 17, a transfer chamber 18, a sputtering device 19, a transfer chamber 20, a chemical vapor deposition (CVD) device 21, a transfer chamber 22, and an unloader 23, which are arranged in series in a transfer direction (from left to right in FIG. 2) of the glass substrate G. The loader 11, the transfer chamber 12, the deposition processing device 13 for forming the light-emitting layer 3, the transfer chamber 14, the work function adjusting film forming device 15, the transfer chamber 16, the etching device 17, the transfer chamber 18, the sputtering device 19, the transfer chamber 20, the chemical vapor deposition (CVD) device 21, the transfer chamber 22, and the unloader 23 are respectively connected to each other by gate valves 24. The loader 11 is a device for loading the glass substrate G into the film forming system 10. The transfer chambers 12, 14, 16, 18, 20, and 22 are devices for receiving and transferring the substrate G between the respective processing devices. The unloader 23 is a device for unloading the glass substrate G out of the film forming system 10.

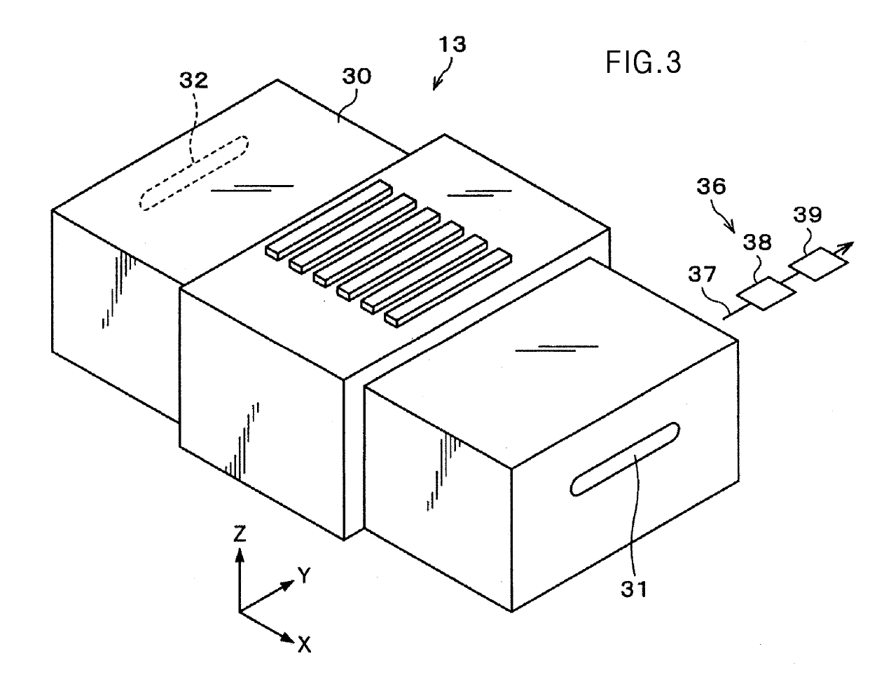

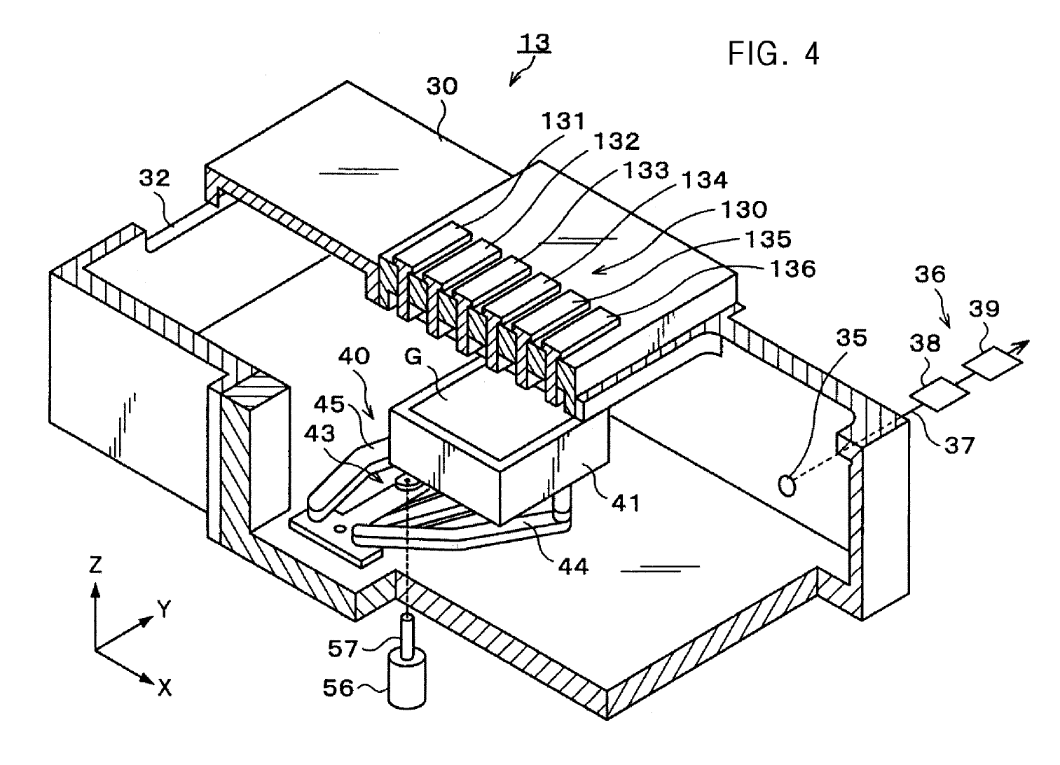

Hereinafter, the deposition processing device 13 will be described in more detail. FIG. 3 is a perspective view of the deposition processing device 13 according to an embodiment of the present invention. FIG. 4 is a partial cross sectional view illustrating the internal structure of the deposition processing device 13.

The deposition processing device 13 according to the present embodiment includes a processing chamber 30 for accommodating the glass substrate G therein. The processing chamber 30 may be formed of aluminum or stainless steel by using a cutting process or a welding process. The processing chamber 30 has long block shape as a whole. A transfer opening 31 is formed in a front surface of the processing chamber 30, and a transfer opening 32 is formed in a rear surface of the processing chamber 30. In the deposition processing device 13, the glass substrate G transferred to the front side of the processing chamber 30 through the transfer opening 32 which is the rear surface of the processing chamber 30. Then, the glass substrate G is unloaded out of the processing chamber 30 through the transfer opening 31. For convenience sake, the direction in which the glass substrate G is transferred is defined as an X-axis, a direction perpendicular to the X-axis on a horizontal plane is defined as a Y-axis, and a direction perpendicular to the X-axis on a vertical plane is defined as a Z-axis.

Referring to FIG. 4, an exhaust hole 35 is formed in a side surface of the processing chamber 30. A depressurization mechanism 36 that is disposed outside of the processing chamber 30 is connected to the exhaust hole 35 via an exhaust pipe 37. The depressurization mechanism 36 includes a turbo molecular pump 38 and a dry pump 39. When the depressurization mechanism 36 operates, the interior of the processing chamber 30 is depressurized to a predetermined pressure.

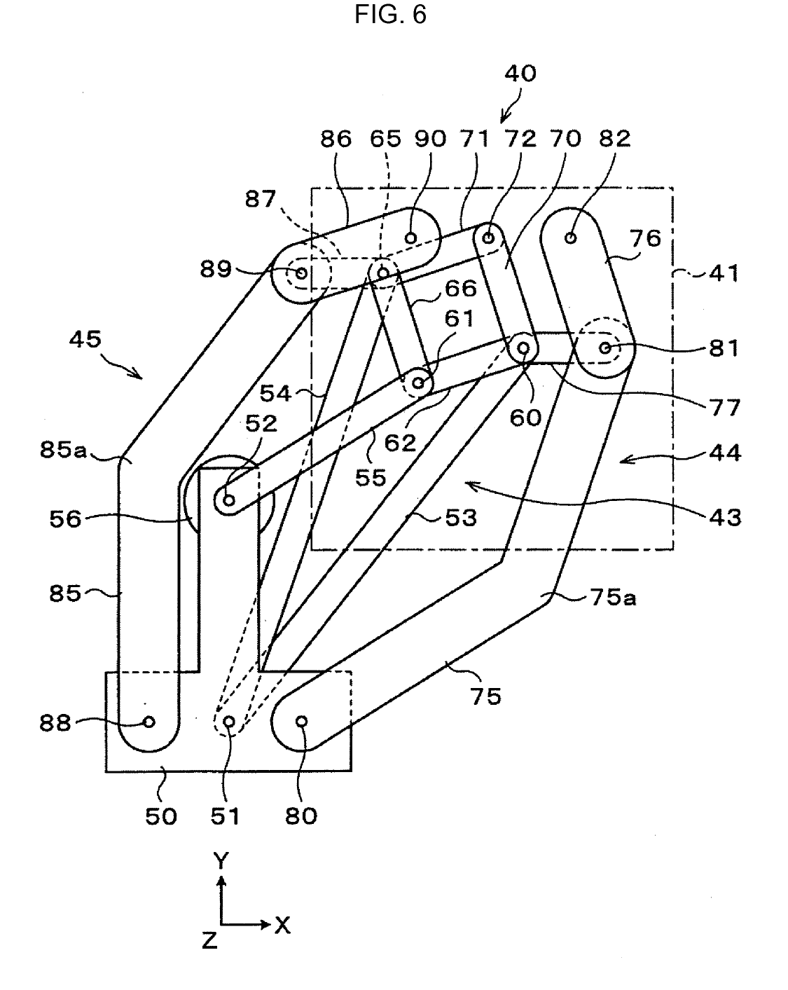

A transfer device 40 for transferring the glass substrate G in the X-axis direction is formed in the processing chamber 30. The transfer device 40 includes a stage 41 holding the glass substrate G, a linear movement mechanism 43 linearly moving the stage 41, and two parallel link mechanisms 44 and 45. As illustrated in FIG. 6, in the present embodiment, a peaucellier linear movement mechanism is used as the linear movement mechanism 43. In the transfer device 40, rotation of the stage 41 is prevented by forming the parallel link mechanisms 44 and 45 at both sides of the linear movement mechanism 43.

First, the linear movement mechanism 43 is described. A holding plate 50 has a T shape and two rotation axes 51 and 52 are formed in the plate 50 with a predetermined interval therebetween in the Y-axis direction. The two rotation axes 51 and 52 are located at the same position in the X-axis direction. (That is, a straight line connecting the rotation axes 51 and 52 is parallel to the Y-axis direction.) The holding plate 50 is fixed to a side or bottom surface of the processing chamber 30. The positions of the two rotation axes 51 and 52 are fixed. Two links 53 and 54 are held on the rotation axis 51. The two links 53 and 54 are rotatable around the rotation axis 51 on a horizontal plane, or an X-Y plane. A single link 55 is fixed to the rotation axis 52. The rotational power of a motor 56 that is a driving source arranged outside the processing chamber 30 is transferred to the rotation axis 52 via a shaft 57. Thus, the link 55 is rotated around the rotation axis 52 on the horizontal plane, or the X-Y plane, due to the rotational power of the motor 56.

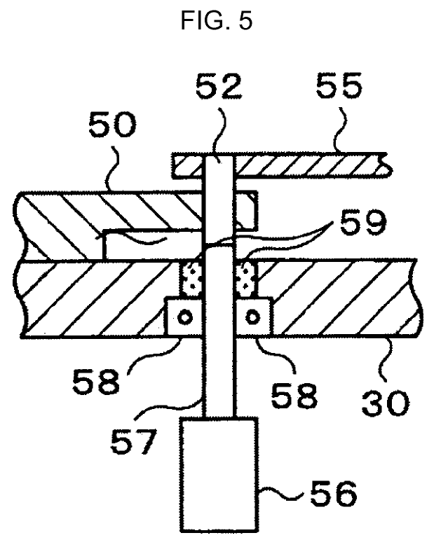

Referring to FIG. 5, the shaft 57 of the motor 56 penetrates the bottom surface of the processing chamber 30 and is connected to the rotation axis 52 fixed to the link 55. A shaft receiving portion 58 and a magnetic fluid 59 as a sealing member are formed at a portion of the bottom surface of the processing chamber 30 where the shaft 57 penetrates. Also, the shaft receiving portion 58 is arranged outside the processing chamber 30, that is, in the air, while the magnetic fluid 59 is arranged inside the processing chamber 30, that is, in a processing atmosphere.

A rotation axis 60 is formed at a leading end of the link 53, while a rotation axis 61 is formed at a leading end of the link 55. The rotation axis 60 at the leading end of the link 53 and the rotation axis 61 at the leading end of the link 55 are connected by a link 62. Both ends of the link 62 are held to be capable of freely rotating on the horizontal plane, or the X-Y plane, with respect to the rotation axes 60 and 61. Likewise, a rotation axis 65 is formed at the leading end of the link 54. The rotation axis 65 at the leading end of the link 54 and the rotation axis 61 at the leading end of the link 55 are connected by a link 66. Both ends of the link 66 are held to be capable of freely rotating on the horizontal plane, or the X-Y plane, with respect to the rotation axes 61 and 65.

Also, an end of a link 70 is held on the rotation axis 60 at the leading end of the link 53. Likewise, an end of a link 71 is held on the rotation axis 65 at the leading end of the link 54. The other ends of the links 70 and 71 are connected by a rotation axis 72. The rotation axis 72 is attached to the lower surface of the stage 41. Both ends of the link 70 are held to be capable of freely rotating on the horizontal plane, or the X-Y plane, with respect to the rotation axes 60 and 72. Likewise, both ends of the link 71 are held to be capable of freely rotating on the horizontal plane, or the X-Y plane, with respect to the rotation axes 65 and 72.

In the linear movement mechanism 43, the lengths of the respective links, or the distance between the respective rotation axes, have the following relationships. The length of the link 53 is the same as that of the link 54. That is, the distance between the rotation axis 51 and the rotation axis 60 is the same as the distance between the rotation axis 51 and the rotation axis 65. Also, the lengths of the links 62, 66, 70, and 71 are all the same. That is, the distance between the rotation axis 60 and the rotation axis 61, the distance between the rotation axis 61 and the rotation axis 65, the distance between the rotation axis 60 and the rotation axis 72, and the distance between the rotation axis 65 and the rotation axis 72 are all the same. In the linear movement mechanism 43 having the peaucellier linkage configured as above, as the link 55 is rotated around the rotation axis 52 on the horizontal plane, or the X-Y plane, the rotation axis 72 may be linearly moved in the X-axis direction in FIG. 6.

Next, the parallel link mechanism 44 is described. In the parallel link mechanism 44, two arms 75 and 76 and a link 77 are added to the links 53 and 70 of the linear movement mechanism 43. A rotation axis 80 is formed on the holding plate 50 having the T shape by being separated by a predetermined interval from the rotation axis 51 in the X-axis direction. The position of the rotation axis 80 is fixed. The two rotation axes 51 and 80 are located at the same Y position in the Y-axis direction. (That is, a straight line connecting the rotation axes 51 and 80 is parallel to the X-axis direction.)

The arm 75 is held on the rotation axis 80. The arm 75 may freely rotate around the rotation axis 80 on the horizontal plane, or the X-Y plane. A rotation axis 81 is formed at the leading end of the arm 75. The rotation axis 60 at the leading end of the link 53 and the rotation axis 81 at the leading end of the arm 75 are connected by the link 77. Both ends of the link 77 are held to be capable of freely rotating on the horizontal plane, or the X-Y plane, with respect to the rotation axes 60 and 81.

Also, an end of the arm 76 is held on the rotation axis 81 at the leading end of the arm 75. A rotation axis 82 is formed at the other end of the arm 76. The rotation axis 82 is attached to the lower surface of the stage 41. Both ends of the arm 76 are held to be capable of freely rotating on the horizontal plane, or the X-Y plane, with respect to the rotation axes 81 and 82.

The lengths of the respective links or arms, or the distance between the respective rotation axes, in the parallel link mechanism 44 have the following relationships. The length of the link 53 is the same as that of the arm 75. That is, the distance between the rotation axis 51 and the rotation axis 60 is the same as the distance between the rotation axis 80 and the rotation axis 81. Also, the length of the link 77, that is, the distance between the rotation axis 60 and the rotation axis 81, is the same as the distance between the rotation axis 51 and the rotation axis 80. As a result, even when the link 53 and the arm 75 rotate on the horizontal plane, or the X-Y plane, a parallelogram made by vertices of the rotation axes 51, 60, 81, and 80 is always formed. Thus, the link 77 is always parallel to a straight line connecting the rotation axes 51 and 80. Also, the link 77 is always parallel to the X-axis direction.

Also, the length of the link 70 is the same as the length of the arm 76. That is, the distance between the rotation axis 60 and the rotation axis 72 is the same as the distance between the rotation axis 81 and the rotation axis 82. Also, the length of the link 77, that is, the distance between the rotation axis 60 and the rotation axis 81, is the same as the distance between the rotation axis 72 and the rotation axis 82. As a result, even when the link 70 and the arm 76 rotate on the horizontal plane, or the X-Y plane, a parallelogram made by vertices of the rotation axes 60, 72, 82, and 81 is always formed. Thus, a straight line connecting the rotation axes 72 and 82 is always parallel to the link 77. Also, a straight line connecting the rotation axes 72 and 82 is always parallel to the X-axis direction.

Also, the parallel link mechanism 45 at the other side has basically the same structure as that of the above-described parallel link mechanism 44. That is, in the parallel link mechanism 45, two arms 85 and 86 and a link 87 are added to the links 54 and 71 of the linear movement mechanism 43. A rotation axis 88 is formed on the holding plate 50 having the T shape by being separated a predetermined interval from the rotation axis 51 in the X-axis direction. However, the rotation axis 88 is located at the opposite side of the holding plate 50 to the rotation axis 80 with the rotation axis 51 interposed therebetween. The position of the rotation axis 88 is fixed. The two rotation axes 51 and 88 are located at the same position with respect to the Y-axis direction. That is, a straight line connecting the rotation axes 51 and 88 is parallel to the X-axis direction.

The arm 85 is held on the rotation axis 88. The arm 85 may freely rotate around the rotation axis 88 on the horizontal plane, or the X-Y plane. A rotation axis 89 is formed at the leading end of the arm 85. The rotation axis 65 at the leading end of the link 54 and the rotation axis 89 at the leading end of the arm 85 are connected by the link 87. Both ends of the link 87 are held to be capable of freely rotating on the horizontal plane, or the X-Y plane, with respect to the rotation axes 65 and 89.

Also, an end of the arm 86 is held on the rotation axis 89 at the leading end of the arm 85. A rotation axis 90 is formed at the other end of the arm 86. The rotation axis 90 is attached to the lower surface of the stage 41. Both ends of the arm 86 are held to be capable of freely rotating on the horizontal plane, or the X-Y plane, with respect to the rotation axes 89 and 90.

The lengths of the respective links or arms, or the distance between the respective rotation axes, in the parallel link mechanism 45 have the following relationships. The length of the link 54 is the same as that of the arm 85. That is, the distance between the rotation axis 51 and the rotation axis 65 is the same as the distance between the rotation axis 88 and the rotation axis 89. Also, the length of the link 87, that is, the distance between the rotation axis 65 and the rotation axis 89, is the same as the distance between the rotation axis 51 and the rotation axis 88. As a result, even when the link 54 and the arm 85 rotate on the horizontal plane, or the X-Y plane, a parallelogram made by vertices of the rotation axes 51, 65, 89, and 88 is always formed. Thus, the link 87 is always parallel to a straight line connecting the rotation axes 51 and 88. Also, the link 87 is always parallel to the X-axis direction.

Also, the length of the link 71 is the same as the length of the arm 86. That is, the distance between the rotation axis 65 and the rotation axis 72 is the same as the distance between the rotation axis 89 and the rotation axis 90. Also, the length of the link 87, that is, the distance between the rotation axis 65 and the rotation axis 89, is the same as the distance between the rotation axis 72 and the rotation axis 90. As a result, even when the link 71 and the arm 86 rotate on the horizontal plane, or the X-Y plane, a parallelogram made by vertices of the rotation axes 65, 72, 90, and 89 is always formed. Thus, a straight line connecting the rotation axes 72 and 90 is always parallel to the link 87. Also, a straight line connecting the rotation axes 72 and 90 is always parallel to the X-axis direction.

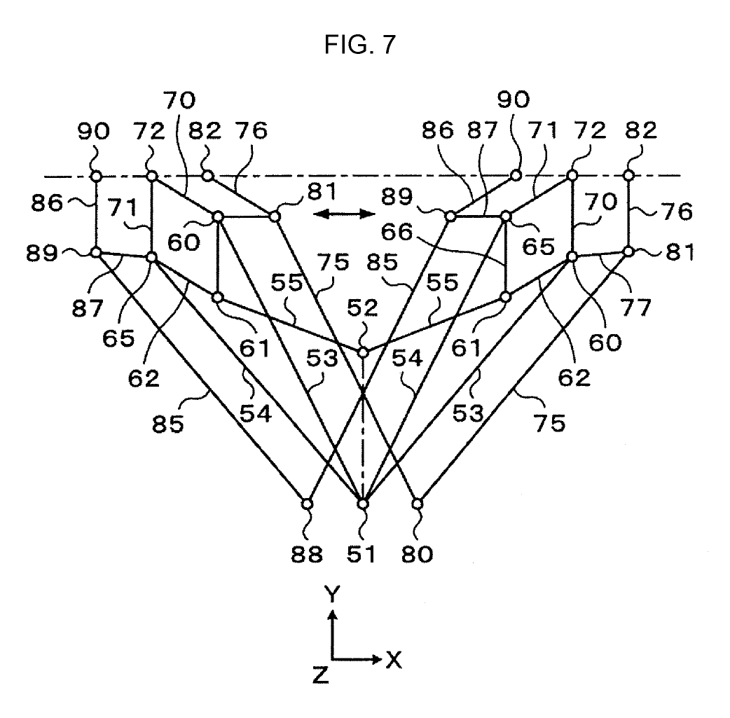

FIG. 7 is a schematic diagram illustrating a change in the positional relationship of the respective links, arms, and rotation axes of the linear movement mechanism 43 and the parallel link mechanisms 44 and 45 constituting the transfer device 40. In the transfer device 40 configured as above, when the rotation axis 72 is linearly moved in the X-axis direction in FIG. 6 by the above-described linear movement mechanism 43, the straight line connecting the three rotation axes 72, 82, and 90 may be always maintained to be parallel to the X-axis direction by the parallel link mechanisms 44 and 45. Thus, by attaching the three rotation axes 72, 82, and 90 to the lower surface of the stage 41, the stage 41 may be linearly moved without being rotated by the cooperation of the linear movement mechanism 43 and the parallel link mechanisms 44 and 45. As a result, in the interior of the processing chamber 30, the transfer device 40 may transfer the glass substrate G in the X-axis direction without rotating the glass substrate G.

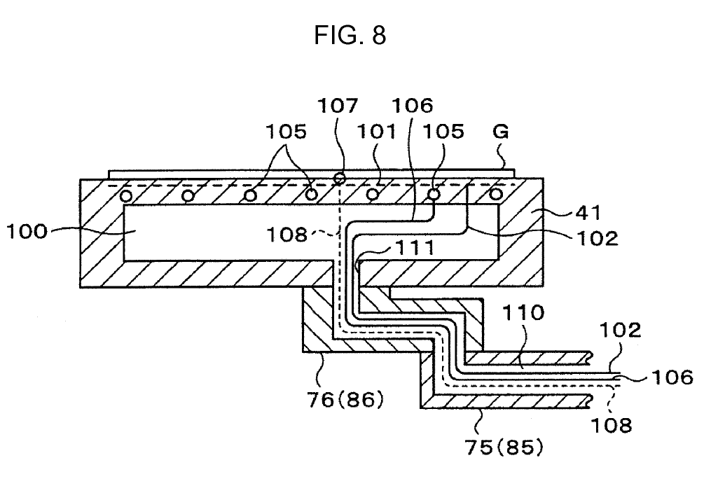

Referring to FIG. 8, a space portion 100 is formed inside the stage 41 to be separated from the internal atmosphere of the processing chamber 30. An electrostatic chuck 101 for holding the glass substrate G disposed on the stage 41 is provided in an upper surface of the stage 41. Electric wiring 102 connected to the electrostatic chuck 101 leads into the space portion 100 of the stage 41.

Also, a heat medium path 105 for controlling the temperature of the glass substrate G disposed on the stage 41 is provided in the upper surface of the stage 41. A fluid path 106 for supplying a heat medium such as ethylene glycol leads into the space portion 100 of the stage 41. Also, an electric heating gas supply portion 107 for supplying a gas for electric heating to a gap between the lower surface of the glass substrate G held on the stage 41 and the upper surface of the stage 41 is provided on the upper surface of the stage 41. A gas pipe 108 for supplying the gas for electric heating, for example, He, to the electric heating gas supply portion 107 leads into the space portion 100 of the stage 41.

An air communication path 110 is formed inside each of the arms 75, 76, 85, and 86 of the above-described parallel link mechanisms 44 and 45. The space portion 100 of the stage 41 is connected to the external atmosphere of the processing chamber 30 by the air communication path 110. Also, a hole 111 for connecting the space portion 100 of the stage 41 to the air communication path 110 in each of the arms 75, 76, 85, and 86 is formed in the lower surface of the stage 41. The hole 111 is formed at the positions of the above-described rotation axes 82 and 90. Although not illustrated, a hole for connecting the air communication path 11 of each of the arms 75, 76, 85, and 86 to the external atmosphere of the processing chamber 30 is formed in a wall surface of the processing chamber 30 in the same manner.

As described above, all of the electric wiring 102 connected to the electrostatic chuck 101, the fluid path 106 for supplying a heat medium to the heat medium path 105, and the gas pipe 108 for supplying a gas for electric heating to the electric heating gas supply portion 107 pass through the air communication path 110 in each of the arms 75, 76, 85, and 86 and thus lead to the outside of the processing chamber 30.

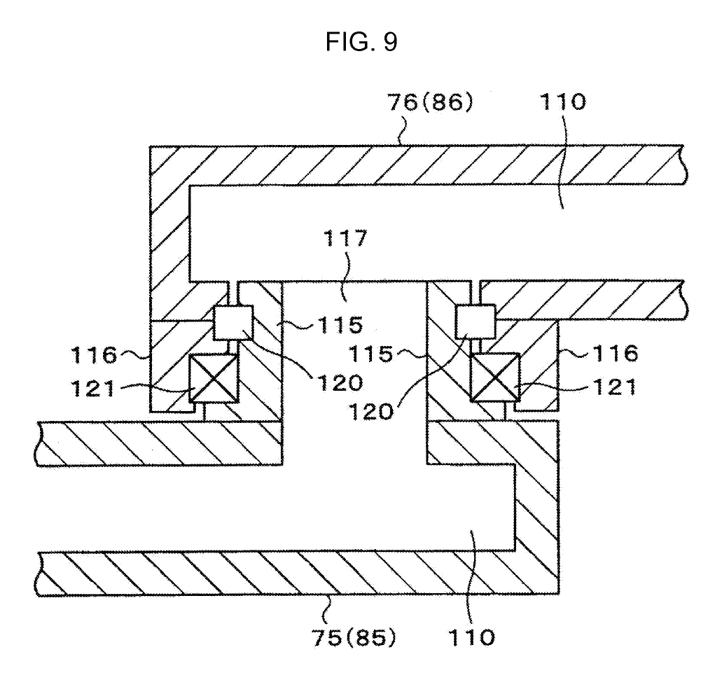

FIG. 9 is a magnified cross-sectional view illustrating the connection structure of the arms 75 and 76 in the parallel link mechanism 44. The arms 75 and 76 are connected to each other to be capable of freely rotating by inserting a convex portion 115 having a circumferential shape and formed at an end portion of the arm 75 at one side into a concave portion 116 having a circumferential shape and formed at an end portion of the arm 76 at the other side. The central axes of the convex portion 115 and the concave portion 116 match the rotation axis 81 that is described above. The air communication paths 110 of the arms 75 and 76 are connected to each other via a path 117 formed in the convex portion 115.

A shaft receiving member 120 and a sealing member 121 are formed between an outer circumferential surface of the convex portion 115 formed at the end portion of the arm 75 at one side and an inner circumferential surface of the concave portion 116 formed at the end portion of the arm 76 at the other side. The sealing member 121 is arranged closer to the internal atmosphere of the processing chamber 30 than the shaft receiving member 120 while the shaft receiving member 120 is arranged close to the atmosphere in each of the arms 75, 76, 85, and 86 sealed by the sealing member 121. For example, a magnetic fluid may be used as the sealing member 121.

Also, although a redundant description is omitted, the arms 85 and 86 in the parallel link mechanism 45 are connected to each other to be capable of freely rotating in the same structure. Accordingly, in the state of being isolated from the internal atmosphere of the processing chamber 30, the space portion 100 of the stage 41 is connected to the external atmosphere of the processing chamber 30 via the air communication path 110 in each of the arms 75, 76, 85, and 86.

Also, although the arms 75, 76, 85, and 86 of the parallel link mechanisms 44 and 45 have been described above, for example, the connection structure using the shaft receiving member 120 and the sealing member 121, or the magnetic fluid, may be similarly used for a connection portion between the arm 76 and the lower surface of the stage 41, a connection portion between the arm 86 and the lower surface of the stage 41, a connection portion between the arm 75 and the wall surface of the processing chamber 30, and a connection portion between the arm 85 and the wall surface of the processing chamber 30. Also, the same connection structure may be used for a connection portion between the respective links of the linear movement mechanism 43 and a connection portion between the link 70 and the stage 41.

Referring to FIG. 6, the arm 75 of the parallel link mechanism 44 includes a bent portion 75a bent away (i.e., to be wide to the outside) from the linear movement mechanism 43. The bent portion 75a increases a bending angle between the arms 75 and 76 at a connection portion between the arms 75 and 76, that is, the position of the rotation axis 81. As described above, although the electric wiring 102 connected to the electrostatic chuck 101, the fluid path 106 for supplying a heat medium to the heat medium path 105, and the gas pipe 108 for supplying a gas for electric heating to the electric heating gas supply portion 107 pass through the air communication path 110 in each of the arms 75 and 76, since a wide bending angle is maintained between the arms 75 and 76, the electric wiring 102, the fluid path 106, or the gas pipe 108 may be prevented from being bent at an acute angle at the connection portion between the arms 75 and 76. Thus, damage or deterioration of the electric wiring 102, the fluid path 106, or the gas pipe 108 is prevented.

Likewise, the arm 85 of the parallel link mechanism 45 includes a bent portion 85a bent away (i.e., to be wide to the outside) from the linear movement mechanism 43. Accordingly, as a wide bending angle is maintained between the arms 85 and 86, the electric wiring 102, the fluid path 106, or the gas pipe 108 may be prevented from being bent at an acute angle at the connection portion between the arms 85 and 86, thereby preventing damage or deterioration.

Referring to FIG. 4, a deposition head or evaporation head 130 for supplying vapor of a film-forming material to the surface of the glass substrate G that is moved by being held on the stage 41 is provided on the upper surface of the processing chamber 30. The deposition head 130 includes a first head 131 for forming the hole transport layer, a second head 132 for forming the non-emissive layer, a third head 133 for forming the blue light emission layer, a fourth head 134 for forming the red light emission layer, a fifth head 135 for forming the green light emission layer, and a sixth head 136 for forming the electron transport layer, which are arranged in the direction in which the stage 41 moves, that is, the X-axis direction.

Next, the work function adjusting film forming device 15 of FIG. 2 forms the work function adjusting layer with respect to the surface of the glass substrate G using a deposition method. The etching device 17 etches each of the formed layers. The sputtering device 19 forms the cathode 2 by sputtering an electrode material such as Ag. The CVD device 21 forms a sealing layer, formed of nitride, for sealing the organic EL device A, wherein the sealing layer is formed by CVD.

In the film forming system 10 configured as above, the glass substrate G loaded into the film forming system 10 by the loader 11 is transferred to the deposition processing device 13 by the transfer chamber 12. In this case, the anode 1 formed of, for example, ITO, is formed in advance in a predetermined pattern on the surface of the glass substrate G.

In the deposition processing device 13, the glass substrate G is disposed on the stage 41 with the surface, or a film forming surface, of the glass substrate G facing upwardly. Before the glass substrate G is transferred into the deposition processing device 13, the interior of the processing chamber 30 of the deposition processing device 13 is depressurized to a predetermined pressure by the operation of the depressurization mechanism 36.

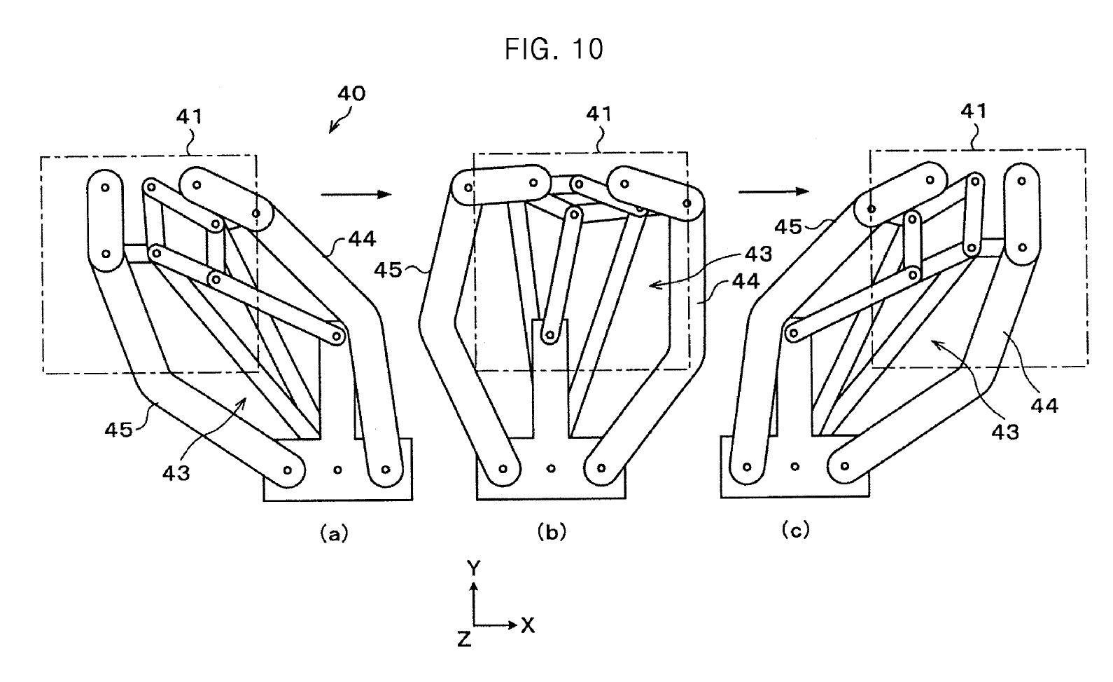

In the processing chamber 30 of the depressurized deposition processing device 13, as illustrated in FIG. 10, the stage 41 is linearly moved in the X-axis direction, without being rotated, by the linear movement mechanism 43 and the parallel link mechanisms 44 and 45 of the transfer device 40. That is, the stage 41 is moved in the X-axis direction by the operation of the peaucellier linear movement mechanism constituting the linear movement mechanism 43. Accordingly, the stage 41 is sequentially and linearly moved as illustrated in (a), (b), and (c) of FIG. 10. Also, during the linear movement, the rotation of the stage 41 is prevented by the existence of the parallel link mechanisms 44 and 45 so that the stage 41 may be moved in parallel to the X-axis as illustrated in (a), (b), and (c) of FIG. 10. During the linear movement of the stage 41, vapor of a film-forming material is supplied from the deposition head 130 toward the surface of the glass substrate G held on the stage 41, and the light-emitting layer 3 is formed and stacked on the surface of the glass substrate G.

Then, the glass substrate G on which the light-emitting layer 3 is formed in the deposition processing device 13 is transferred, by the transfer chamber 14, into the work function adjusting film forming device 15. Then, the work function adjusting layer is formed on the surface of the glass substrate G in the work function adjusting film forming device 15.

Next, the transfer chamber 16 transfers the glass substrate G into the etching device 17 in which the shape of each layer is adjusted. Next, the transfer chamber 16 transfers the glass substrate G into the sputtering device 19 in which the cathode 2 is formed. Next, the transfer chamber 16 transfers the glass substrate G into the CVD device 21 in which the organic EL device A is sealed. The organic EL device A fabricated as above is transferred out of the film forming system 10 via the transfer chamber 22 and the unloader 23.

In the film forming system 10, the stage 41 may be easily and linearly moved by using the linear movement mechanism 43 and the parallel link mechanisms 44 and 45 of the peaucellier linkage, and using the rotational power of the motor 56, in the depressurized processing chamber 30 of the deposition processing device 13. Also, also, during the transfer, the stage 41 is prevented from being moved in the Y-axis direction, that is, being deviated sideways, being rotated around the X-axis direction, that is, rolling, and being rotated around the Z-axis direction, that is, yawing. Accordingly, while the stage 41 is aligned properly, the light-emitting layer 3 may be formed and stacked appropriately on the surface of the glass substrate G.

Also, the atmosphere of the space portion 100 formed in the stage 41 is connected to the external atmosphere of the processing chamber 30 via the air communication path 110 in each of the arms 75, 76, 85, and 86. The electric wiring 102 connected to the electrostatic chuck 101, the fluid path 106 for supplying a heat medium to the heat medium path 105, and the gas pipe 108 for supplying a gas for electric heating to the electric heating gas supply portion 107 pass through the air communication path 110 and thus lead to the outside of the processing chamber 30. Thus, the hold, movement, and temperature control of the glass substrate G may be suitably performed from the outside of the processing chamber 30. Also, the bent portions 75a and 85a are formed at the arms 75 and 85 of the parallel link mechanisms 44 and 45, respectively, and thus wide bending angles are maintained between the arms 75 and 76, and the arms 85 and 86, so that the electric wiring 102, the fluid path 106, and the gas pipe 108 may be prevented from being damaged or deteriorated. Also, since normal atmospheric pressure is formed in the space portion 100 of the stage 41, a layout, for example, a lift pin, is made easy.

While the present invention has been particularly shown and described with reference to preferred embodiments using specific terminologies, the embodiments and terminologies should be considered in descriptive sense only and not for purposes of limitation. Therefore, it will be understood by those of ordinary skill in the art that various changes in form and details may be made therein without departing from the spirit and scope of the present invention as defined by the following claims. For example, in the above-described transfer device 40, the two parallel link mechanisms 44 and 45 are formed with respect to the linear movement mechanism 43. However, when the electric wiring 102 or the heat medium path 105 arranged in the air communication path 110 is not long, only one of the parallel link mechanisms 44 and 45 may be acceptable.

Also, to prevent the forming of a layer on the respective links or arms forming the linear movement mechanism 43 or the parallel link mechanisms 44 and 45, the linear movement mechanism 43 or the parallel link mechanisms 44 and 45 are covered with a cover. Also, in addition to the magnetic fluid, an O-ring may be used as a sealing member formed between the respective links, the respective arms, and the link or arm and the stage.

Also, although an application example of the present invention has been described based on the deposition processing device 13 used to form the light-emitting layer 3 of the organic EL device A, the present invention may be applied to a vacuum processing device used for the processing of various other electronic devices. For example, the present invention may be applied to various processing devices such as film forming (PVD or CVD), etching, heat treatment, or light radiation. Also, the present invention may be applied to a transfer chamber for transferring a substrate. Also, when the present invention is applied to the deposition processing device 13 of the above-described embodiment, the rotation of the motor 56 may be controlled to make the transfer speed of the glass substrate G uniform. Meanwhile, when the present invention is applied to the transfer chamber, the control of the rotation of the motor 56 to make the transfer speed of the glass substrate G uniform may be omitted.

The substrate G to be processed may be a substrate of various shape such as, a glass substrate, a silicon substrate, or a horn or circular shaped substrate. Also, in FIG. 2, the film forming system 10 includes the loader 11, the transfer chamber 12, the deposition processing device 13 for forming the light-emitting layer 3, the transfer chamber 14, the work function adjusting film forming device 15, the transfer chamber 16, the etching device 17, the transfer chamber 18, the sputtering device 19, the transfer chamber 20, the CVD device 21, the transfer chamber 22, and the unloader 23, which are arranged in series in the transfer direction of the substrate G. However, the number and arrangement of the respective processing devices may be changed.

According to the present invention, in the depressurized interior of processing chamber, the stage which holds the substrate may linearly move without rotating, by the linear movement mechanism and parallel link mechanism. Specifically, by using a peaucellier linear movement mechanism, rotational moving power of motor etc. is used so that the apparatus may become compact, the interior of the processing chamber may be maintained in clean atmosphere, and the stage may linearly move in an easy way. Also, the atmosphere of the space portion formed in the stage is connected to the external atmosphere of the processing chamber via the air communication path formed in the parallel link mechanism. Thus, the electric wiring of the electrostatic chuck, electric wiring of the shaft motor, piping of the heat medium, and the supply piping for the electric heating gas etc. can be arranged inside the parallel link mechanism. As a result, holding the chuck, moving the stage, and temperature control of the substrate may be suitably performed from the outside of the processing chamber.

The present invention may be applied to the field of manufacturing organic EL devices, for example.

What is claimed is:

1. A processing device for processing a substrate, the processing device comprising:
a processing chamber which receives the substrate;
a depressurization mechanism which depressurizes the interior of the processing chamber;
a stage which holds the substrate and is arranged in the processing chamber;
a linear movement mechanism which linearly moves the stage and is arranged in the processing chamber; and
a parallel link mechanism which prevents the rotation of the stage and is arranged in the processing chamber,
wherein a space portion isolated from the internal atmosphere of the processing chamber is formed in the stage, and an air communication path that allows the space portion to communicate with the external atmosphere of the processing chamber is formed in the parallel link mechanism.

2. The processing device of claim 1, wherein the linear movement mechanism comprises a peaucellier linear movement mechanism.

3. The processing device of claim 1, further comprising a driving source which drives the linear movement mechanism, wherein the driving source is arranged outside the processing chamber.

4. The processing device of claim 1, wherein the parallel link mechanism comprises a plurality of arms connected to be capable of being freely rotated with respect to each other.

5. The processing device of claim 4, wherein a convex portion having a cylindrical shape and formed at one of the plurality of arms is inserted in a concave portion having a cylindrical shape and formed at the other arm, at a connection portion between the plurality of arms forming the parallel link mechanism, to connect the plurality of arms to be capable of being freely rotated with respect to each other, and a shaft receiving member and a sealing member are formed between an outer circumferential surface of the convex portion and an inner circumferential surface of the concave portion.

6. The processing device of claim 5, wherein the sealing member is arranged closer to the internal atmosphere of the processing chamber than the shaft receiving member, and the shaft receiving member is arranged close to atmosphere in the arm sealed by the sealing member.

7. The processing device of claim 5, wherein the sealing member comprises a magnetic fluid.

8. The processing device of claim 4, wherein further comprising a bent portion formed on one of the plurality of arms forming the parallel link mechanism to be wide to the outside, to increase a bending angle between the arms at a connection portion between the plurality of arms.

9. The processing device of claim 4, wherein an electric wiring is arranged in the arm.

10. The processing device of claim 4, wherein a fluid path is arranged in the arm.

11. The processing device of claim 4, wherein a gas pipe is arranged in the arm.

12. The processing device of claim 1, further comprising a deposition head which supplies vapor of a film-forming material to the substrate held on the stage, wherein the deposition head is provided in the processing chamber.

13. The processing device of claim 12, wherein the film-forming material comprises a film-forming material of a light-emitting layer of an organic electroluminescence (EL) device.
